(19) United States
(12) Patent Application Publication
(10) Pub. No.: US 2007/0242514 A1
(43) Pub. Date: Oct. 18, 2007

(54) NAND-structured nonvolatile memory cell

(75) Inventors: David S. Choi, Cupertino, CA (US); Kyu Hyun Choi, Cupertino, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: O2IC, Inc., Santa Clara, CA (US)

(21) Appl. No.: 11/373,818

(22) Filed: Mar. 10, 2006

Related U.S. Application Data
(60) Provisional application No. 60/660,948, filed on Mar. 10, 2005.

(51) Int. Cl. G11C 11/34

(52) U.S. Cl. 365/185.17

(57) ABSTRACT

A multitude of NAND flash memory cells coupled to a bit line of a NAND flash memory array includes, in part, a highly doped source region coupled to a first terminal and a highly doped drain region coupled to a second terminal of the multitude of cells. Each NAND memory cell includes, in part, a first gate layer and a second gate layer both adapted to receive a voltage. The second gate layers of the NAND flash memory cells are connected to one another.

### CROSS-REFERENCES TO RELATED APPLICATIONS

The present application claims benefit under 35 USC 119(e) of U.S. provisional application No. 60/660,948, filed Mar. 10, 2005, entitled “NAND-Structured Nonvolatile Memory Cell”, the content of which is incorporated herein by reference in its entirety. The present application is also related to U.S. Pat. No. 6,965,145, entitled “Non-Volatile Memory Device”, which is incorporated herein by reference in its entirety.

### BACKGROUND OF THE INVENTION

This present invention relates to semiconductor circuits. More particularly, the invention provides an improved NAND-structure non-volatile memory cell unit.

Nonvolatile semiconductor memory devices have been widely used to store data in electronic devices. A nonvolatile semiconductor memory device, such as Electronically Erasable Programmable Read Only Memory (EEPROM), or Metal Nitride Oxide Semiconductor(MNOS), retains its charge even after the power applied thereto is turned off. Therefore, where loss of data due to power failure or termination is unacceptable, nonvolatile memory is used to store the data.

A NAND-structured EEPROM memory is a specific type of EEPROM memory, and is commonly used to store data in electronic devices. In a NAND-structured EEPROM memory, memory cells are grouped into blocks, and each block includes a plurality of arrays of memory cells. These arrays of memory cells are also called NAND cell array, NAND cell units, or NAND cell strings.

Each NAND cell unit consist of a drain region formed in the substrate, which is coupled to the bit line associated with the NAND cell, a source region formed in the substrate, and a series of floating gates overlaying the channel region between the source and the drain.

Each floating gate in the series of floating gates overlaying the channel is coupled to a word line node of the NAND cell. As merely an example, if there are 8 floating gates in the memory cell, there would be 8 word line nodes that correspond with each of the 8 floating gates.

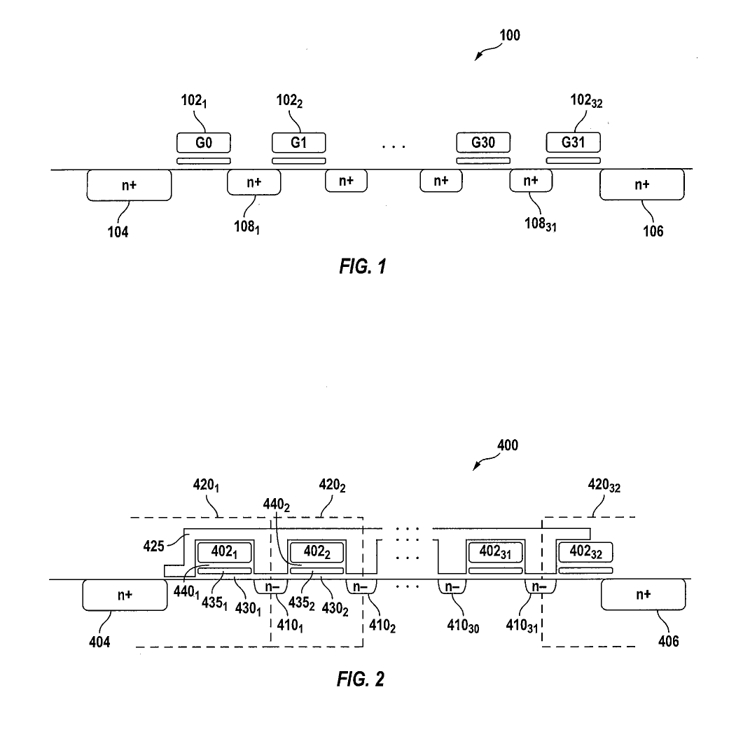

As merely an example, FIG. 1 is a cross sectional view of a NAND cell unit, as known in the prior art. In certain variations of the NAND cell unit, there may be additional select transistors attached to the NAND cell unit (not shown).

Improving the writing speed of the NAND type memory continues to be a challenge when the speed of the memory is of great importance. Digital cameras, for example, require large amounts of data to be written to storage devices such as NAND type memory devices, in a short period of time.

Often when NAND type devices are deployed in battery-operated portable electronic devices, such as digital cameras or cellular phones, the power consumption of the NAND-type device becomes a factor in the battery life of the portable device.

In current conventional implementations, NAND cells are typically programmed using Fowler-Nordheim tunneling. The Fowler-Nordheim tunneling method of programming the devices offers less current than hot-electron injection methods and therefore consumes less power. However, Fowler-Nordheim tunneling is typically slower than hot-electron injection methods.

To program a particular cell in the conventional NAND cell unit using Fowler-Nordheim electron tunneling, the bitline is first biased at 0V. Then, a high voltage, e.g. 15-20V, is applied to the control gate corresponding to the particular cell to be written. A relatively high voltage, e.g. 10V, is applied to the control gates of the rest of the transistors, which act as pass gates. The high voltage on the control gate causes Fowler-Nordheim electron tunneling, which raises the threshold voltage of that gate, effectively programming the cell.

To read a particular cell in the conventional NAND cell unit, a voltage of 0V is applied to the control gate corresponding to the particular cell to be read. A relatively high read voltage is applied to the rest of the control gates of the NAND cell unit, so that the rest of the control gates will turn on. A sense-amplifier is then used to determine the current on the bitline and thus the contents of the cell.

To erase the contents of a conventional NAND cell unit, electrons are ejected from each of floating gates into the channel using Fowler-Nordheim electron tunneling. This is done by applying 0V to each of the wordlines and applying a high voltage to the array p-well.

In conventional NAND cells, the shared channel region between two neighboring control gates is composed of a highly doped silicon substrate, like that of the silicon substrate that composes source and drain regions. As a result, the shared channel region between two neighboring control gates has a high resistance value. FIG. 1 shows a prior art NAND cell string 100 that includes a multitude of gate terminals 102₁, 102₂ . . . 102₃₂, an N⁺ source region 104, an N⁺ drain region 106, and a multitude of shared N⁺ source/drain regions 108₁, 108₂ . . . 108₃₂.

Accordingly, there continues to exist a need for faster and lower power consuming NAND-type nonvolatile devices. While the invention is described in conjunction with the preferred embodiments, this description is not intended in any way as a limitation to the scope of the invention. Modifications, changes, and variations, which are apparent to those skilled in the art can be made in the arrangement, operation and details of construction of the invention disclosed herein without departing from the spirit and scope of the invention.

### SUMMARY OF THE INVENTION

In accordance with one embodiment of the present invention, a multitude of NAND flash memory cells coupled to a bit line of a NAND flash memory array includes, in part, a highly doped source region coupled to a first terminal and a highly doped drain region coupled to a second terminal of the multitude of cells. Each NAND memory cell includes, in part, a first gate layer and a second gate layer both adapted to receive a voltage. The second gate layers of the NAND flash memory cells are connected to one another.

### DETAILED DESCRIPTION OF THE INVENTION

According to the present invention, an improved memory device and method is provided. More particularly, the invention provides an improved NAND-type nonvolatile semiconductor memory cell. Although the invention has been applied to a single integrated memory circuit in a memory application, there can be other alternatives, variations, and modifications. For example, the invention can be applied to embedded memory applications, including those with logic or micro circuits, and the like.

In accordance with the present invention, a string of NAND memory cells includes, in part, a substrate region coupled to the first terminal of the memory cell string; a drain terminal coupled to a bit line associated with the memory cell string; a source terminal coupled to the first terminal of the memory cell string; a first series of gates spaced apart from each other at fixed distances and that are of fixed multiple of, e.g., 8 gates; and a second series of gates spaced apart from each other at fixed distances and that are of the same quantity as the first series of gates and that overlay the first series of gates.

The second series of gates are connected together and are also coupled to another terminal of the memory cell. The first memory cell in the string has a source region formed in the substrate. The last memory cell in the string has a drain region formed in the substrate. During the actual operation the source and drain can be interchangeable.

The mask layer material used in the second series of gates is different from the mask layer material used in the first series of gates such that the voltages applied to the any of the gates in the first layer of gates do not affect the voltage in the second series of gates and vice versa.

The second series of gates are arranged such that the channel region formed under first gate of the second series of gates exists between the source and the channel region formed under the first gate of the first series and the channel regions formed under the remaining gates of the second series exist between the channel regions formed under first series of gates.

The present invention differs from conventional NAND-type nonvolatile memories by including the second series of gates that are not present in the prior art. Instead, the first series of gates form memory transistors in series, where the first gate acts as a gate of a first memory transistor, the second gate acts as a gate of a second memory transistor, and so forth such that the last gate acts as a gate of a last memory transistor, and the drain of the first memory transistor acts as a source of the second memory transistor, the drain of the second memory transistor acts as a source of the third memory transistor, and so forth. Also the second gate acts as an element to reduce the resistor value by increasing the bias voltage during the read.

In the present invention, the drain of the first memory transistor, which is also the source of the second memory transistor, is replaced by a channel region formed by the second gate of the second series of gates, and so forth. In this way the source resistor value is drastically reduce during the read.

The accompanying drawings, which are incorporated in form or in part of the specification, illustrate embodiments of the invention and, together with the description, serve to explain the principles of the invention.

FIG. 2 is a cross-sectional view of a NAND cell string 400, in accordance with one embodiment of the present invention. NAND cell string 400 is shown as including 32 NAND cells 420₁, 420₂ . . . 420₃₂. It is understood that a NAND cell string in accordance with the present invention may include more or fewer than 32 cells. NAND cell string 400 is shows, in part, as including an N⁺ source region 404, an N⁺ drain region 406, and 31 lightly doped N⁻ or P⁻ (not shown) shared source/drain regions 410₁, 410₂ . . . 412₃₁. Each NAND cell 420ᵢ, where i is an index ranging from 1 to 32 in this embodiment, is shown as including, in part, a control gate 402ᵢ and a guiding gate 425. The guiding gates of all 32 NAND cells are connected to one another and are formed during the same masking layer. The guiding gate 425 covers the control gates 402ᵢ.

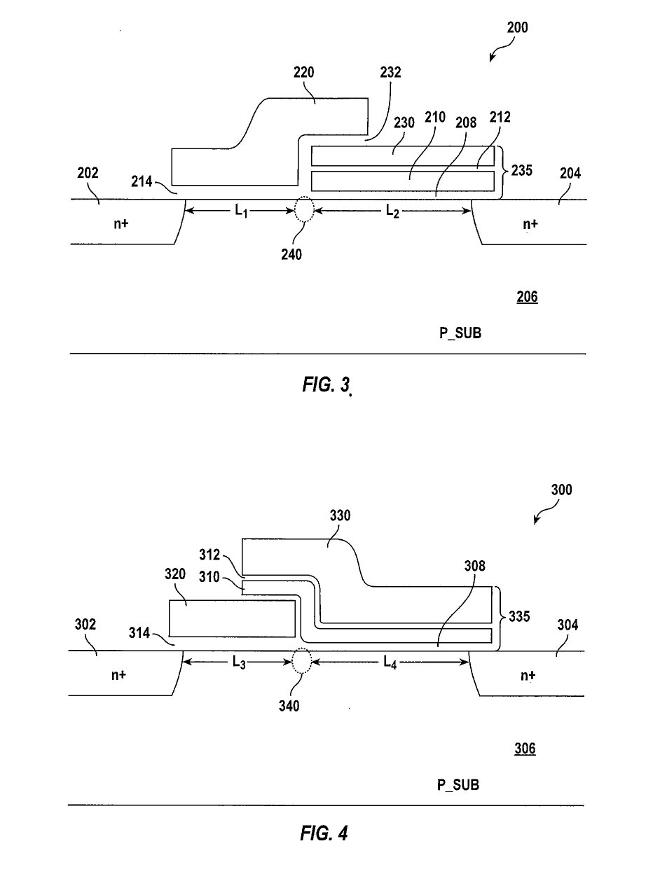

In one embodiment, each of regions 404 and 406 have doping concentration of 10¹⁹ to 10²⁰ atoms/cm³. Each of the lightly doped N⁻ or P⁻ regions 410₁, 410₂ . . . 412₃₁ has a concentration of 10¹⁶ to 10¹⁷ atoms/cm³. Formed below the control gate 402ᵢ of each NAND cells 420ᵢ is a an oxide layer 430ᵢ, a nitride layer 435ᵢ and an oxide layer 440ᵢ. Each of NAND cells 420₁, 420₂ . . . 420₃₂ is a non-volatile memory device corresponding to non-volatile memory devices 200 or 300 shown in FIG. 3 and 4 that are described in U.S. Pat. No. 6,965,145, entitled “Non-Volatile Memory Device”, and that is incorporated herein by reference in its entirety. As seen from FIG. 2 guiding gate 425 only partially overlaps control gate 402₃₂.

FIG. 6 is a cross-sectional view of a NAND cell string 500, in accordance with another embodiment of the present invention. NAND cell string 500 is similar to NAND cell string 400 except that in NAND cell string 500, regions 435ᵢ are formed using polysilicon that is adapted to float. Therefore, each NAND cell 420ᵢ of NAND cell string 500, in addition to a control gate layer 402ᵢ and a guiding gate layer 425 also includes a floating polysilicon gate layer 435ᵢ.

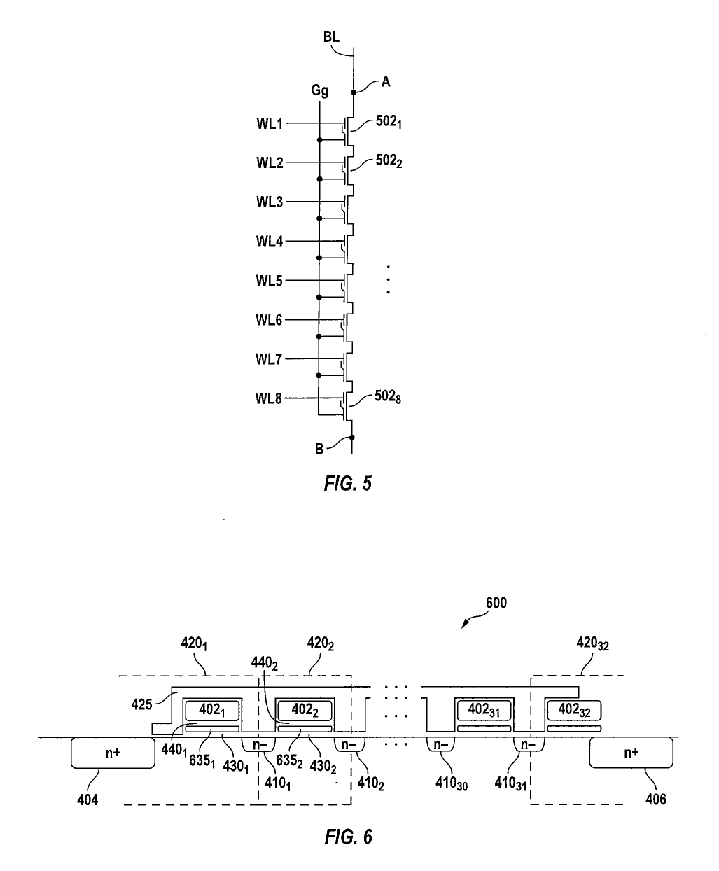

FIG. 5 is a transistor level schematic diagram of a NAND flash string 500 having disposed therein 8 NAND memory cells, 502₁, 502₂ . . . 502₈, in accordance with one exemplary embodiment of the present invention. This diagram is merely an example, which should not unduly limit the scope of the claims herein. One of ordinary skill in the art would recognize many other variations, modifications, and alternatives. The guiding gates of the NAND memory cells 502₁, 502₂ . . . 502₈ are coupled to terminal Gg. The control gates of NAND memory cells 502₁, 502₂ . . . 502₈ are respectively coupled to terminals WL1, . . . , WLn, wherein in this embodiment n is equal to 8. NAND flash string 600 may be part of a memory array (not shown) disposed in a semiconductor Integrated Circuit (IC) adapted, among other functions, to store and supply the stored data. Terminal BL typically forms the bitline of such a memory array and terminals WL1, . . . , WLn forms the word lines of such a memory array. Node A (i.e., bit line BL) is coupled to the drain terminal of NAND memory cell 502₁ and corresponds to region 406 of NAND cell string 400 shown in FIG. 2. Node B is coupled to the source terminal of NAND memory cell 5028 and corresponds to region 404 of NAND cell string 400 shown in FIG. 2.

The NAND flash memory cells may be programmed during a write cycle. During such a write cycle, assuming a supply voltage of 3.5 volts, the word line (control gates) associated with the memory cell intended to store a 1 is raised to a high voltage of between 12 to 18 volts. The control gates of the memory cells intended not to be programmed are raised to a voltage of between, for example, 4 to 5 volts. The guiding gate (the third terminal of the memory cell) Gg voltage is raised to a fixed voltage, e.g., 0.5˜3V. During a programming cycle, the source terminal is grounded and the drain terminal receives a voltage of, for example, between 6 to 10 volts. The hot electron injection method, the Fowler-Nordheim tunneling method, or a combination of thereto methods, may be used to program the memory cell. The programming occurs using source side injection.

The memory cell may be read during a read cycle. During such a read cycle, the guiding gate is raised to the supply voltage Vcc, and the control gates are raised to a voltage of, for example, between 3 to 5 volts. The drain terminal is also raised to a voltage of, for example, between 1 to 3 volts. The source terminal is grounded.

The memory cell may be erased during an erase cycle. During such an erase cycle and using tunneling, the source and drain terminals are coupled to the ground potential. The guiding gate receives a voltage of between 0 to −4 volts. The control gates receive a voltage of between −10 to −16 volts. To erase via hot hole injection, the drain terminal is 10 to 12 volts, the source is grounded, the control gate receives a voltage of between −7 to −10 volts, and the guiding gate receive a voltage of 0 to −3 volts.

FIG. 6 is a cross-sectional view of a NAND cell string 600, in accordance with another embodiment of the present invention. NAND cell string 600 is similar to NAND cell string 400 except that in NAND cell string 600, regions 635ᵢ are formed using polysilicon that is adapted to float. Therefore, each NAND cell 420ᵢ of NAND cell string 600, in addition to a control gate layer 402ᵢ and a guiding gate layer 425 also includes a floating polysilicon gate layer 635ᵢ.

What is claimed is:

1. A non-volatile memory structure comprising a plurality of NAND flash memory cells and comprising:
a highly doped source region coupled to a first one of the plurality of NAND flash memory cells;
a highly doped drain region coupled to a last one of the plurality of NAND flash memory cells;
a plurality of lightly doped source/drain regions shared by the plurality of NAND flash memory cells; wherein each NAND memory cell comprises a first gate layer and a second gate layer both adapted to receive a voltage; wherein said second gate layer of the plurality of NAND flash memory cells are connected to one another.

2. The non-volatile memory structure of claim 1 wherein the second gate layer of the last one of the plurality of NAND memory cells partially overlaps the first gate layer disposed therein.

3. The non-volatile memory structure of claim 2 wherein each NAND memory cell further comprises a floating poly gate layer positioned below the first gate layer and above the channel region of its associated NAND cell.

4. The non-volatile memory structure of claim 3 wherein said lightly doped source/drain regions are P⁻ regions.
